(19) United States
(12) Patent Application Publication
(10) Pub. No.: US 2010/0232491 A1
(43) Pub. Date: Sep. 16, 2010

(54) RECEIVER AND RECEIVING METHOD

(75) Inventor: Takaya HAYASHI, Kyoto (JP)

Correspondence Address: MCDERMOTT WILL & EMERY LLP, 600 13TH STREET, NW, WASHINGTON, DC, 20005-3096, US

(73) Assignee: Panasonic Corpoation, Osaka (JP)

(21) Appl. No.: 12/789,017

(22) Filed: May 27, 2010

Related U.S. Application Data
(63) Continuation of application No. PCT/JP2008/003503, filed on Nov. 27, 2008.

(30) Foreign Application Priority Data
Nov. 28, 2007 (JP) 2007-307449

(51) Int. Cl. H03H 7/30

(52) U.S. Cl. 375/229

(57) ABSTRACT

A receiver for receiving a signal transmitted through a transmission channel includes an equalizer and a first quality calculator that obtains a first quality value of the received signal. The equalizer includes a first channel estimation unit that estimates a first channel response of the transmission channel from the received signal using a first estimation scheme, and a second channel estimation unit that estimates a second channel response of the transmission channel from the received signal using the second estimation scheme. The equalizer equalizes the received signal using the first or second channel response and outputs the equalized signal. A portion of the second channel estimation unit halts depending on the first quality value.

### CROSS-REFERENCE TO RELATED APPLICATION

This is a continuation of PCT International Application PCT/JP2008/003503 filed on Nov. 27, 2008, which claims priority to Japanese Patent Application No. 2007-307449 filed on Nov. 28, 2007. The disclosures of these applications including the specifications, the drawings, and the claims are hereby incorporated by reference in their entirety.

### BACKGROUND

The present disclosure relates to a receiver that receives a digitally modulated signal and demodulates the signal.

In a digital terrestrial television broadcasting in Japan and Europe, OFDM (Orthogonal Frequency Division Multiplexing) is used as a transmission scheme. According to the OFDM, information such as pictures and sounds is transmitted by a plurality of carriers that are orthogonal to each other.

Generally, in the OFDM, scattered pilot signals (SPs) are sent in addition to the data to be transmitted. As one example thereof, FIG. 2 shows a portion of a transmission format of the digital terrestrial television broadcasting in Japan. In FIG. 2, white circles show data carriers, and black circles show the SPs. Since amplitude, phase and insertion position of the SP are known, a receiving side generally estimates influence of distortion (channel response) caused by multipath propagation in the transmission channel using the SPs, and eliminates the influence. That is, equalization is performed.

When the equalization corresponding to the data carrier is carried out using the SPs, the received OFDM signal is converted into signals of frequency domain by FFT (Fast Fourier Transform), and channel responses corresponding to the known SPs are obtained. Further, the channel responses corresponding to the SPs are interpolated using a filter, channel response corresponding to each data carrier between the SPs is estimated, and the OFDM signal in the frequency domain is divided by the obtained channel response.

The following schemes are known as a channel estimation scheme.

(I) A scheme in which interpolation is once carried out in a symbol direction (time direction) and then, interpolation is carried out in a carrier direction (frequency direction).
(II) A scheme in which interpolation only in the carrier direction (frequency direction) is carried out.

Results of estimation of channel response is largely varied in some cases depending upon the interpolation method and characteristics of a filter used in the interpolation in each of receiving environments having different conditions, such as in terms of AWGN (Additive White Gaussian Noise), multipath and fading.

Therefore, there is known a technique in which a receiving side previously prepares a plurality of interpolation methods and filters suitable for estimated various receiving environments, optimal one of the interpolation methods or filters is selected in accordance with the receiving environments, and it is used for the equalization operation.

For example, Japanese Patent Publication No. 2006-140987 describes a receiver having estimation units of channel responses corresponding to the (I) and (II), respectively, and selecting between the estimation units in accordance with the conditions.

Japanese Patent Publication No. 2006-311385 describes a technique in which in the estimation units of channel response corresponding to the (I), a plurality of filters having different characteristics is prepared as interpolation filters in the carrier direction, and a selection is made between the filters in accordance with the conditions.

However, if a plurality of estimation units of channel response simultaneously operates, power consumption of the receiver becomes large. This tendency becomes high as the number of estimation units of channel response is increased. This tendency reduces duration of a battery when the receiver is used in a portable receiver.

### SUMMARY

In a receiver capable of estimating channel response using a plurality of schemes, it is an object of the present invention to reduce power consumption while keeping the receiver performance.

A receiver for receiving a signal transmitted through a transmission channel according to embodiments of the present invention includes an equalizer and a first quality calculator that obtains a first quality value of the received signal. The equalizer includes a first channel estimation unit that estimates a first channel response of the transmission channel from the received signal using a first estimation scheme, and a second channel estimation unit that estimates a second channel response of the transmission channel from the received signal using the second estimation scheme. The equalizer equalizes the received signal using the first or second channel response and outputs the equalized signal. A portion of the second channel estimation unit halts depending on the first quality value.

According to this, since a portion of the second channel estimation unit halts depending on the quality value of the received signal, it is possible to stop the second channel estimation unit only when it is unnecessary to operate the second channel estimation unit, power consumption can be reduced while keeping the receiver performance.

A receiving method for receiving a signal transmitted through a transmission channel according to the embodiments of the present invention includes the steps of: estimating a first channel response of the transmission channel from the received signal using a first estimation scheme, estimating a second channel response of the transmission channel from the received signal using a second estimation scheme, equalizing the received signal using the first or second channel response, obtaining a quality value of the received signal, and halting a portion of operation for estimating the second channel response depending on the quality value.

According to the embodiments of the present invention, it is possible to inexpensively reduce the power consumption while keeping the receiver performance.

### BRIEF DESCRIPTION OF THE DRAWINGS

FIG. 1 is a block diagram showing a configuration of a receiver according to a first embodiment of the present invention;

FIG. 2 is an explanatory diagram showing one example of a transmission format of an OFDM signal;

FIG. 3 is a block diagram showing an example of a computing element of a channel estimation unit controlled by an operation controller in FIG. 1;

FIG. 4 is a block diagram showing a configuration of a receiver according to a modification of the first embodiment of the invention;

FIG. 5 is a block diagram showing a configuration of a receiver according to a second embodiment of the invention;

FIG. 6 is a block diagram showing a configuration of a receiver according to a modification of the second embodiment of the invention; and

FIG. 7 is a block diagram showing a configuration of a receiver according to a third embodiment of the invention.

### DETAILED DESCRIPTION

Embodiments of the present invention will be described with reference to the drawings.

### First Embodiment

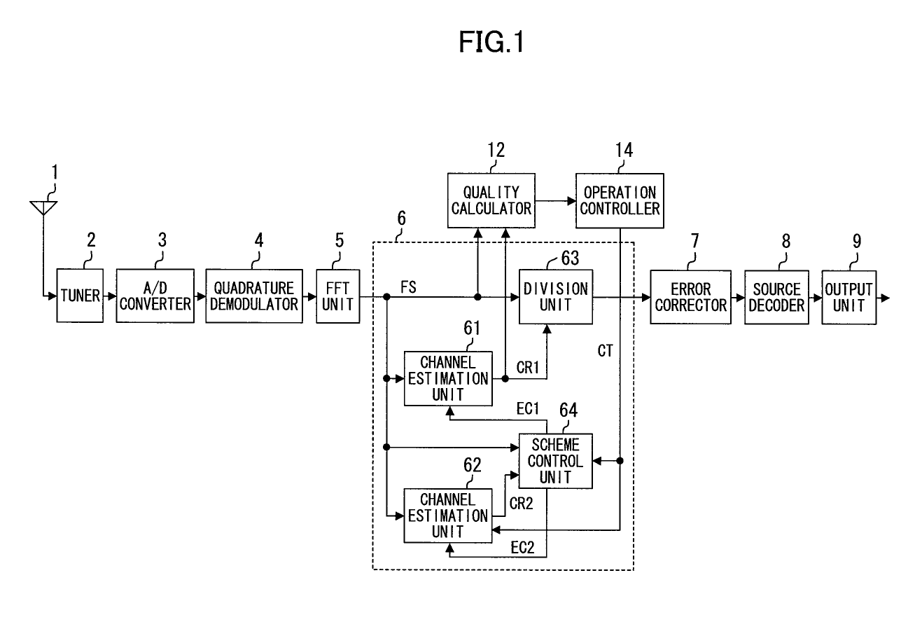

FIG. 1 is a block diagram showing a configuration of a receiver according to a first embodiment of the invention. The receiver in FIG. 1 includes a tuner 2, an A/D converter 3, a quadrature demodulator 4, an FFT unit 5, an equalizer 6, an error corrector 7, a source decoder 8, an output unit 9, a quality calculator 12, and an operation controller 14.

An antenna 1 receives OFDM signals of an RF (Radio Frequency) band sent through a transmission channel between a transmitting antenna and the antenna 1, and supplies the received signals to the tuner 2. The tuner 2 extracts an OFDM signal of a desired channel from the OFDM signals of the RF band supplied from the antenna 1, frequency converts the extracted OFDM signal, and outputs the obtained OFDM signal in an IF band to the A/D converter 3. The A/D converter 3 converts the OFDM signal in the IF band which is output from the tuner 2 from an analogue signal to a digital signal, and outputs the converted signal to the quadrature demodulator 4.

The quadrature demodulator 4 frequency converts the digitized OFDM signal in the IF band that was output from the A/D converter 3, outputs the result thereof to the FFT unit 5 as a baseband OFDM signal. The FFT unit 5 converts the baseband OFDM signal output from the quadrature demodulator 4 from a signal in a time domain to a signal in a frequency domain by FFT (Fast Fourier Transform), and outputs the result thereof to the equalizer 6 as an OFDM signal FS of the frequency domain.

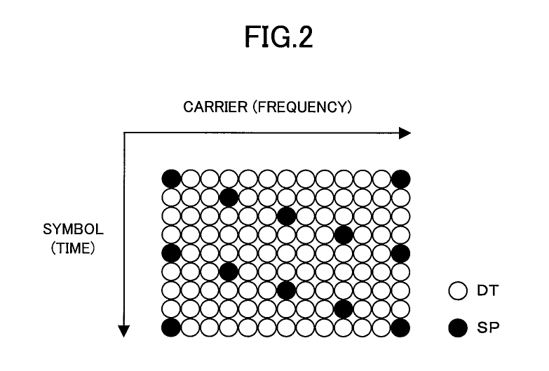

FIG. 2 is an explanatory diagram showing one example of a transmission format of the OFDM signal. FIG. 2 shows OFDM signals in the frequency domain in unit of symbols, white circles show data carriers DTs, and black circles show the SPs (Scattered Pilot signals).

The equalizer 6 estimates frequency characteristic of a transmission channel through which the received signal is transmitted (hereinafter referred to as channel response), and reduces or eliminates waveform distortion caused by multipath, fading and the like from the OFDM signal FS in the frequency domain that was output from the FFT unit 5. That is, equalization is performed. The equalizer 6 outputs the result obtained by the equalization to the error corrector 7 as an equalized signal, and outputs a portion of signals used for the processing to the quality calculator 12.

The quality calculator 12 calculates a quality value of the received signal in accordance with the signal output from the equalizer 6. In this embodiment, the quality calculator 12 obtains the quality value based on the OFDM signal FS in the frequency domain and a channel response estimated by the equalizer 6, and outputs the quality value to the operation controller 14. The operation controller 14 generates an operation control signal CT in accordance with the quality value output from the quality calculator 12, and outputs the signal CT to the equalizer 6. The equalizer 6 halts a portion of its elements depending on the operation control signal CT.

The error corrector 7 carries out various kinds of error correcting operations such as demapping, deinterleave, Viterbi decoding and Reed-Solomon decoding for the equalized signal output from the equalizer 6, and outputs the obtained result to the source decoder 8 as a transport stream. The source decoder 8 separates the transport stream output from the error corrector 7 into a video stream, an audio stream and other data stream. When these streams are compressed by MPEG (Moving Picture Experts Group) or the like, the source decoder 8 expands the streams, and outputs the result thereof to the output unit 9 as a video signal, an audio signal or other data. The output unit 9 includes a display and a speaker, displays the video signal output from the source decoder 8 on the display, outputs the audio signal to the speaker, and outputs the other data to an external device.

The receiver in FIG. 1 will be described in more detail. The equalizer 6 includes channel estimation units 61 and 62, a division unit 63, and a scheme control unit 64. The scheme control unit 64 outputs, to the channel estimation unit 62, a scheme control signal EC2 indicating one of a plurality of predetermined channel estimation schemes.

The channel estimation unit 62 selects one of the plurality of predetermined estimation schemes in accordance with the scheme control signal EC2 output from the scheme control unit 64, and estimates a channel response corresponding to a data carrier from a received signal (OFDM signal FS in frequency domain) using the selected estimation scheme and a filter. The channel estimation unit 62 outputs the estimated channel response CR2 to the scheme control unit 64.

The scheme control unit 64 calculates a quality value corresponding to the estimation scheme indicated to the channel estimation unit 62 using the received channel response CR2 and the OFDM signal FS in the frequency domain. The scheme control unit 64 equalizes the OFDM signal FS in the frequency domain by the channel response CR2, and obtains, as the quality value, a variance of signal points of the obtained signal from a reference point. In this specification, the reference point of the signal point is an ideal symbol point on a plane of rectangular coordinates.

The scheme control unit 64 repeats the above-described operation while successively selecting one of the estimation schemes to be indicated. That is, the channel estimation unit 62 obtains a channel response corresponding to an estimation scheme that is successively selected from a plurality of predetermined estimation schemes. The scheme control unit 64 calculates a quality value corresponding to the selected estimation scheme. When the calculation of the quality values respectively corresponding to all of the estimation schemes is completed, the scheme control unit 64 selects one of the estimation schemes corresponding to the optimal quality value, and outputs a scheme control signal EC1 indicating the selected estimation scheme, thereby informing the channel estimation unit 61 of the selected estimation scheme. In other words, the scheme control unit 64 selects the optimal estimation scheme from the plurality of predetermined estimation schemes based on the channel response obtained by the channel estimation unit 62, and informs the channel estimation unit 61 of the selected estimation scheme.

The channel estimation unit 61 selects the informed one of the plurality of predetermined estimation schemes in accordance with the scheme control signal EC1 output from the scheme control unit 64, and estimates a channel response corresponding to a data carrier from the received signal (OFDM signal FS in the frequency domain) using the selected estimation scheme and a filter or the like. The channel estimation unit 61 outputs the estimated channel response CR1 to the division unit 63 and the quality calculator 12.

The division unit 63 equalizes the OFDM signal FS in the frequency domain by dividing the signal FS by the channel response CR1 output from the channel estimation unit 61, i.e., reduces or eliminates waveform distortion introduced by the transmission channel. The division unit 63 outputs the result of the equalization to the error corrector 7 as an equalized signal. When a modulation scheme of the OFDM signal FS is a modulation scheme in which information is not transmitted with an amplitude, such as QPSK (Quaternary Phase Shift Keying), the OFDM signal FS may be multiplied by a complex conjugate of the channel response CR1 instead of being divided by the channel response CR1. In this case, the division unit 63 may be omitted.

Basically, the channel estimation schemes used in the channel estimation units 61 and 62 are schemes in which channel responses corresponding to SPs included in the received signal are first obtained, the channel responses corresponding to the SPs are interpolated in the symbol direction (time direction) and carrier direction (frequency direction), thereby obtaining channel responses with respect to data carriers. Only the interpolation in the carrier direction may be carried out without interpolation in the symbol direction. As the estimation scheme, it is preferable that schemes having different estimation characteristics (different filter coefficients are used in each of the schemes) are selected from a plurality of schemes suitable for expected various channel conditions.

For example, a plurality of schemes suitable for expected channel conditions are selected from a plurality of schemes having different interpolation filter characteristics in the symbol direction, a plurality of schemes having different interpolation filter characteristics in the carrier directions, and schemes in which only interpolation in the carrier direction is carried out without interpolation in the symbol direction. With this, channel estimation schemes suitable for various receiving environments are selected, equalization is performed by using a suitably obtained channel response and thus, high capabilities of demodulation and error correction can be obtained.

The quality calculator 12 calculates a quality value of the received signal from a channel response CR1 estimated by the channel estimation unit 61 and an OFDM signal FS in the frequency domain, and outputs the result of the calculation to the operation controller 14. The quality calculator 12 equalizes the OFDM signal FS in the frequency domain by the channel response CR1, and obtains, as a quality value, variance of the signal points of the obtained signal from a reference point. In this case, a cost of a device that obtains the quality value is not high. Since the quality value can be obtained using the channel response CR1 used for equalization by the division unit 63, it is possible to stably calculate the quality value.

When the quality value output from the quality calculator 12 is equal to or higher than a predetermined value, the operation controller 14 determines that the quality of the received signal is sufficiently good, generates an operation control signal CT indicating a halt of operation, and outputs the same to the channel estimation unit 62 and the scheme control unit 64.

The channel estimation unit 62 includes a computing element. When the operation control signal CT indicates a halt of operation, at least a portion of the channel estimation unit 62 halts. That is, in this case, the channel estimation unit 62 stops operation such as filter calculation required for estimating a channel response, stops a clock supplied to the computing element, or fixes a level of a signal that is input to the computing element for filter calculation (to a level indicative of a value 0, for example).

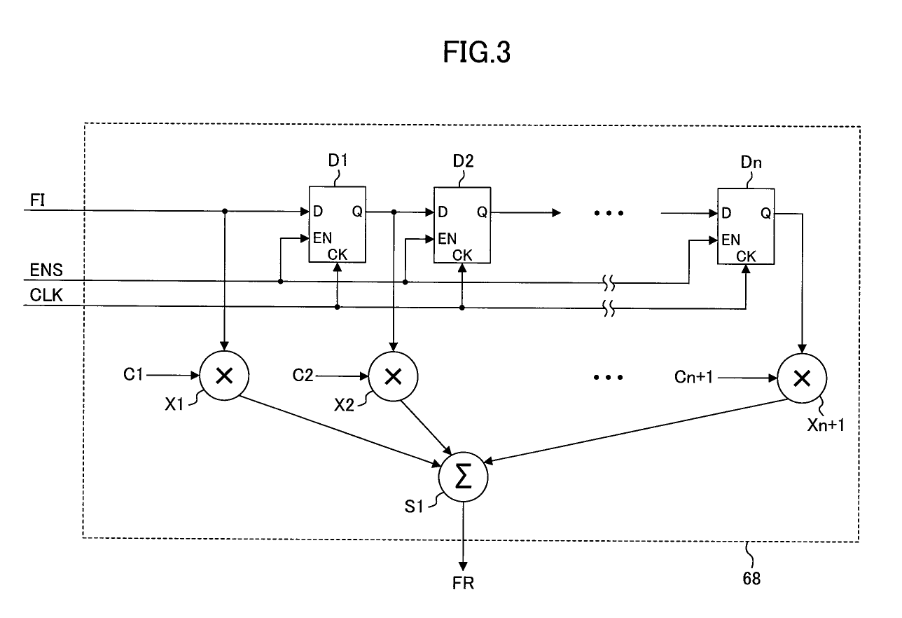

FIG. 3 is a block diagram showing an example of a computing element of the channel estimation unit 62 controlled by the operation controller in FIG. 1. The computing element 68 in FIG. 3 carries out filter calculation for estimating a channel response, and includes n delay elements D1, D2, . . . , Dn (n is a natural number), n+1 multipliers X1, X2, . . . , Xn+1, and an adder S1. An enable signal ENS and a clock CLK are input to each of the delay elements D1 to Dn.

The delay element D1 delays the filter input data FI, and outputs the same to the next delay element D2. The delay element D2 delays output data of the delay element D1, and outputs the same to the next delay element. Other delay elements also delay the outputs of the previous delay elements and output the same. Filter coefficients C1 to Cn+1 correspond to the multipliers X1 to Xn+1, respectively. Outputs of the delay elements D1 to Dn are input to the multipliers X2 to Xn+1, respectively. The multiplier X1 multiplies the filter input data FI and the filter coefficient C1 together, and outputs the obtained product to the adder S1. Each of the multipliers X2 to Xn+1 multiplies the output of the corresponding one of the delay elements D1 to Dn by the corresponding one of the filter coefficients C2 to Cn+1, and outputs the obtained product to the adder S1. The adder S1 obtains a total sum of the products from the multipliers X1 to Xn+1, and outputs the result thereof as filter output data FR.

When the operation control signal CT indicates a halt of operation, the channel estimation unit 62, for example, brings a level of an enable signal ENS that controls operations of the delay elements D1 to Dn into a level indicating that the operation should be stopped, stops supply of clock CLK to the delay elements D1 to Dn, or maintains a constant value of the filter input data FI (0, for example). With this, operations of the constituent elements of the computing element 68 can be stopped and as the result, power consumed by the channel estimation unit 62 can be reduced.

The scheme control unit 64 includes a computing element. Similarly, when the operation control signal CT indicates a halt of operation, the scheme control unit 64 stops at least a portion thereof. That is, in this case, the scheme control unit 64 stops operations such as calculation of a quality value, stops clock that is to be supplied to the computing element, or fixes (to a value 0, for example) a level of a signal that is to be input to the computing element for calculating the quality value. The computing element of the scheme control unit 64 is, for example, also constituted in the same manner as the computing element in FIG. 3, and is controlled in the same manner as the computing element in FIG. 3.

When there exists a disturbance such as AWGN and multipath in a transmission channel, or when a signal is received while the receiver is moving, a quality value that is output from the quality calculator 12 becomes less than a predetermined value in some cases. In this case, the operation controller 14 determines that the quality of the received signal is not sufficiently good, and generates the operation control signal CT indicating operation. At that time, the channel estimation unit 62 and the scheme control unit 64 carry out operations such as calculation as usual. The channel estimation unit 62 and the scheme control unit 64 determine an appropriate channel estimation scheme suitable for a channel condition, and the division unit 63 performs equalization using a channel response obtained by that estimation scheme. Therefore, quality of the equalized signal is maintained and errors can be reduced.

According to this embodiment, as described above, when the condition of the transmission channel is relatively good, the quality calculator 12 determines that the quality value is sufficiently good, and the operation controller 14 generates an operation control signal CT that indicates a halt of operation. At that time, since the channel estimation unit 62 and the scheme control unit 64 halt the operation of the computing element or in effect halt the operation of the computing element, power consumed by the operation such as calculation can be reduced.

### Modification of First Embodiment

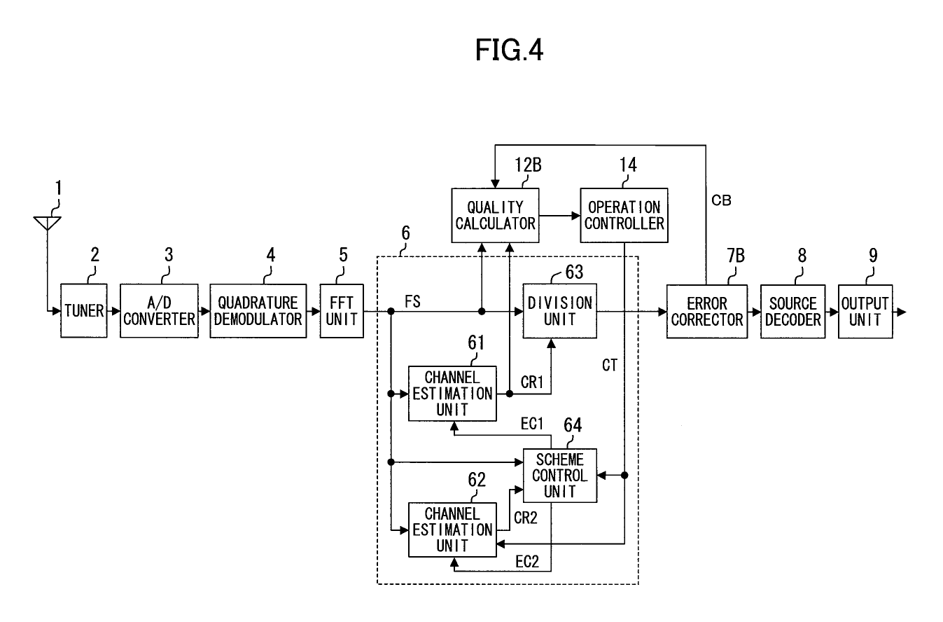

FIG. 4 is a block diagram showing a configuration of a receiver according to a modification of the first embodiment of the invention. The receiver in FIG. 4 is different from the receiver in FIG. 1 in that the former receiver includes an error corrector 7B and a quality calculator 12B instead of the error corrector 7 and the quality calculator 12. The error corrector 7B outputs, to the quality calculator 12B, a number of bits whose errors were corrected as a corrected bit number CB. The error corrector 7B operates in the same manner as the error corrector 7 in other respect.

The quality calculator 12B adds up the corrected bit number CB, obtains a quality value of the received signal based on the obtained added value, and outputs the quality value to the operation controller 14. When the added value is less than a predetermined value, the quality calculator 12B sets the quality value as a value that is equal to or higher than a threshold value, and when the added value is equal to or higher than the predetermined value, the quality calculator 12 sets the quality value as a value lower than the threshold value, for example. The quality calculator 12B may obtain the quality value only based on the added value, or may calculate a quality value of the received signal from the channel response CR1 estimated by the channel estimation unit 61 and the OFDM signal FS in the frequency domain, and may output lower one of this quality value and the quality value based on the added value, similarly to the quality calculator 12.

Since quality of information such as images transmitted by the OFDM signal is prone to be reflected in a quality value obtained based on the corrected bit number CB, information such as images having higher quality can be obtained by the receiver in FIG. 4.

### Second Embodiment

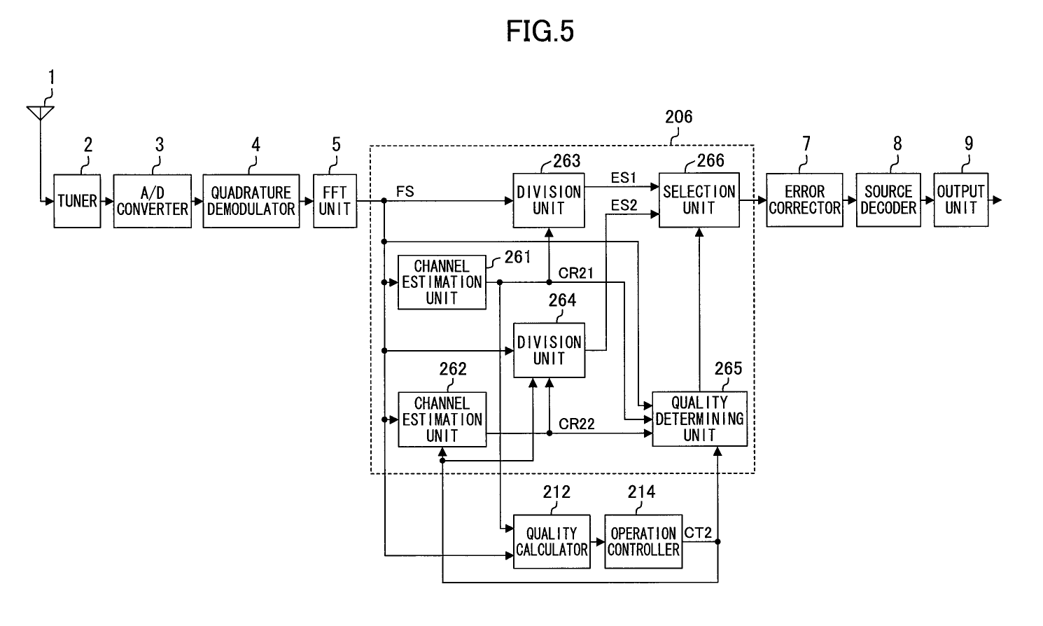

FIG. 5 is a block diagram showing a configuration of a receiver according to a second embodiment of the invention. The receiver in FIG. 5 is different from the receiver in FIG. 1 in that the former receiver includes an equalizer 206, a quality calculator 212 and an operation controller 214 instead of the equalizer 6, the quality calculator 12 and the operation controller 14. Since other elements are the same as those of the receiver in FIG. 1, they are designated with the same reference numbers and description thereof is omitted.

The equalizer 206 in FIG. 5 includes channel estimation units 261 and 262, division units 263 and 264, a quality determining unit 265, and a selection unit 266. The channel estimation unit 261 and the channel estimation unit 262 calculate channel responses CR21 and CR22 corresponding to data carriers from a received signal (OFDM signal FS in frequency domain) using different predetermined estimation schemes.

The division unit 263 equalizes the OFDM signal FS in the frequency domain output from the FFT unit 5 by dividing the OFDM signal FS by the channel response CR21, i.e., reduces or eliminates a waveform distortion introduced by the transmission channel. The division unit 263 outputs the result of the equalization to the selection unit 266 as an equalized signal ES1. The division unit 264 equalizes the OFDM signal FS in the frequency domain by dividing the OFDM signal FS by the channel response CR22, and outputs the result thereof to the selection unit 266 as an equalized signal ES2.

The quality determining unit 265 first calculates a quality value of the received signal corresponding to the channel response CR21 from an OFDM signal FS in the frequency domain and the channel response CR21. Similarly, the quality determining unit 265 calculates a quality value of the received signal corresponding to the channel response CR22 from the OFDM signal FS in the frequency domain and the channel response CR22. At that time, the quality determining unit 265 equalizes, for example, the OFDM signal FS in the frequency domain by the channel responses CR21 or CR22, and obtains a variance of signal points of the obtained signal from the reference point as a quality value.

The quality determining unit 265 determines which one of the quality values corresponding to the channel responses CR21 and CR22 is a better quality value, and outputs, to the selection unit 266, a selection signal indicative of one of the channel responses CR21 and CR22 corresponding to the better quality value. The selection unit 266 selects one of the equalized signals ES1 and ES2. The selected signal is obtained using a channel response indicated by the selection signal output from the quality determining unit 265. The selection unit 266 outputs the result of the selection to the error corrector 7 as an equalized signal. In other words, the equalizer 206 equalizes the received signal using one of the channel responses CR21 and CR22 indicated by the determination result of the quality determining unit 265.

The channel estimation schemes used in the channel estimation units 261 and 262 basically obtain a channel response with respect to a data carrier by obtaining channel responses corresponding to SPs included in the received signal and interpolating the channel responses corresponding to the SPs in the symbol direction and the carrier direction. Only interpolation in the carrier direction may be carried out without the interpolation in the symbol direction. As the estimation scheme, it is preferable that schemes having different estimation characteristics (different filter coefficients, for example) are selected from a plurality of schemes suitable for individual channel conditions.

For example, one scheme is selected for each of the channel estimation units 261 and 262 from a plurality of schemes having different interpolation filter characteristics in the symbol direction, from a plurality of schemes having different interpolation filter characteristics in the carrier direction, or from schemes for carrying out interpolation in the carrier direction without interpolation in the symbol direction. The selected schemes are different from each other and suitable for expected channel conditions. With this, suitable channel estimation schemes are selected in accordance with various receiving environment and equalization is carried out by using suitably obtained channel responses. Therefore, high capabilities of demodulation and error correction can be obtained.

Similarly to the quality calculator 12 in FIG. 1, the quality calculator 212 calculates a quality value of a received signal from the channel response CR21 estimated by the channel estimation unit 261 and an OFDM signal FS in the frequency domain, and outputs the result of the calculation to the operation controller 214.

When the quality value output from the quality calculator 212 is equal to or higher than a predetermined value, the operation controller 214 determines that the quality of the received signal is sufficiently good, generates an operation control signal CT2 indicating a halt of the operation, and outputs the same to the channel estimation unit 262, the division unit 264, and the quality determining unit 265. When the operation control signal CT2 indicates a halt of operation, the quality determining unit 265 outputs a selection signal indicative of the channel response CR21 to the selection unit 266.

The channel estimation unit 262 includes a computing element. When the operation control signal CT2 indicates a halt of operation, at least a portion of the channel estimation unit 262 halts. That is, in this case, the channel estimation unit 62 halts operation such as filter calculation that is required for estimating a channel response, halts the clock that is to be supplied to the computing element, or maintains a constant level (a level indicative of a value 0, for example) of a signal input to the computing element for filter calculation.

The division unit 264 includes a computing element. Similarly, when the operation control signal CT2 indicates a halt of operation, at least a portion of the division unit 264 halts. That is, in this case, the division unit 264 halts the dividing calculation, halts the clock that is to be supplied to the computing element, or maintains a constant level (a level indicative of a value 0, for example) of a signal input to the computing element for the dividing calculation.

The quality determining unit 265 includes a computing element. Similarly, when the operation control signal CT2 indicates a halt of operation, at least a portion of the quality determining unit 265 halts. That is, in this case, the quality determining unit 265 halts the calculation of a quality value, halts the clock that is to be supplied to the computing element, or maintains a constant level (a level indicative of a value 0, for example) of a signal input to the computing element for the calculation of the quality value. The computing elements of the channel estimation unit 262, the division unit 264 and the quality determining unit 265 have the same configurations and are controlled in the same manner as, for example, the computing elements in FIG. 3.

When the quality value output from the quality calculator 212 is less than a predetermined value, the operation controller 214 determines that it is not appropriate to use the channel response CR21, and generates the operation control signal CT2 indicating operation. At that time, the channel estimation unit 262, the division unit 264 and the quality determining unit 265 carry out operation such as calculation as usual. An appropriate channel estimation scheme suitable for a channel condition is determined by the quality determining unit 265, and a signal that was equalized using a channel response obtained by that estimation scheme is selected. Therefore, it is possible to keep a quality of the equalized signal, and to reduce errors.

According to this embodiment, as described above, when the channel condition is relatively good, the quality calculator 212 determines that the quality value is sufficiently good, and the operation controller 14 generates an operation control signal CT2 indicating a halt of the operation. At that time, since the channel estimation unit 262, the division unit 264, and the quality determining unit 265 halt the operation of the computing elements, or in effect halt the operation of the computing elements, power consumed for the operation such as calculation can be reduced.

Although the receiver includes the two channel estimation units 261 and 262 in this embodiment, the receiver may include three or more channel estimation units. In this case, it is preferable that the receiver includes an equal number of division units as the channel estimation units, and includes a quality determining unit that makes a selection from a plurality of channel estimation units like the quality determining unit 265.

Although the selection unit 266 selects one of the outputs of the division units 263 and 264 in this embodiment, the equalizer 206 may select one of the channel responses CR21 and CR22 in accordance with a selection signal output from the quality determining unit 265, and the OFDM signal FS in the frequency domain may be divided by the selected channel response.

### Modification of Second Embodiment

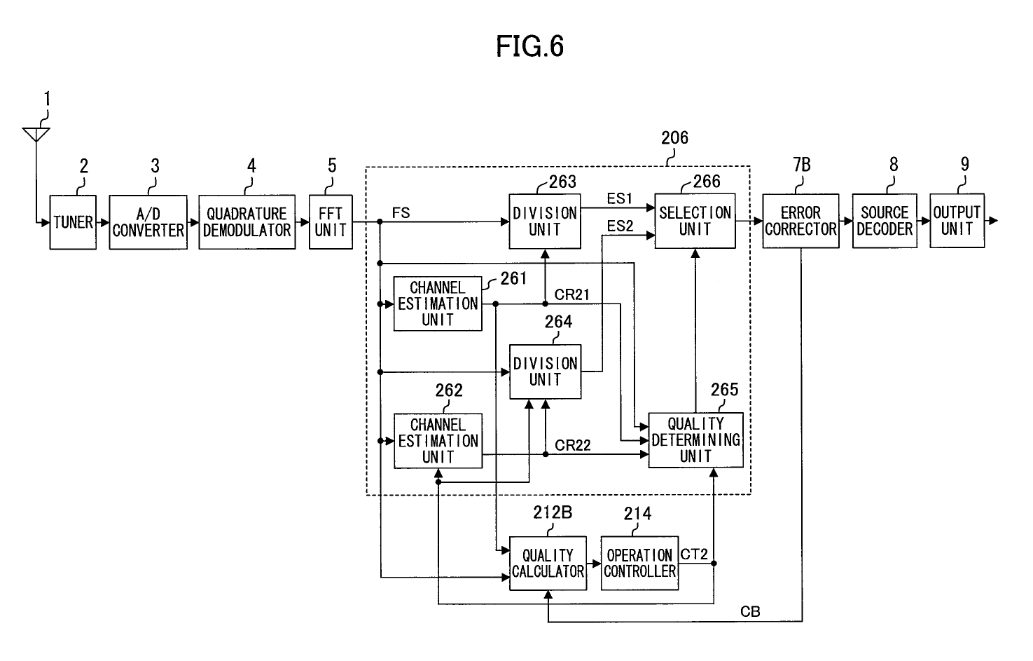

FIG. 6 is a block diagram showing a configuration of a receiver according to a modification of the second embodiment of the invention. The receiver in FIG. 6 is different from the receiver in FIG. 5 in that the former receiver includes an error corrector 7B and a quality calculator 212B instead of the error corrector 7 and the quality calculator 212. The error corrector 7B substantially has the same structure as that described with reference to FIG. 4.

The quality calculator 212B adds up the corrected bit number CB, obtains a quality value of the received signal based on the obtained added value, and outputs the same to the operation controller 214. The quality calculator 212B defines the quality value as a value equal to or higher than a threshold value when the added value is lower than a predetermined value, and defines the quality value as a value lower than the threshold value when the added value is equal to or higher than the predetermined value. The quality calculator 212B may obtain the quality value only based on the added value, or similarly to quality calculator 212, may calculate a quality value of the received signal from the channel response CR21 estimated by the channel estimation unit 261 and the OFDM signal FS in the frequency domain, and may output lower one of this quality value and a quality value based on the added value.

Since a quality of information such as images transmitted by the OFDM signal is prone to be reflected in the quality value obtained based on the corrected bit number CB, information such as images having a higher quality can be obtained by the receiver in FIG. 6.

### Third Embodiment

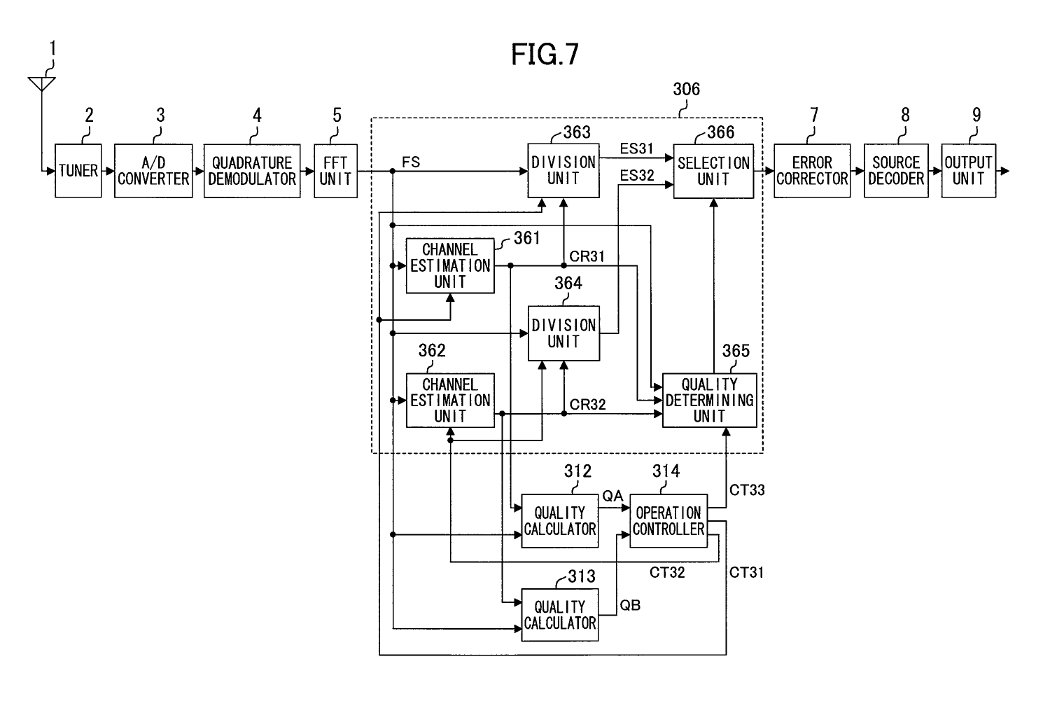

FIG. 7 is a block diagram showing a configuration of a receiver according to a third embodiment of the invention. The receiver in FIG. 7 is different from the receiver in FIG. 1 in that the former receiver includes an equalizer 306, quality calculators 312 and 313, and an operation controller 314 instead of the equalizer 6, the quality calculator 12, and the operation controller 14. Since other elements are the same as those of the receiver in FIG. 1, they are designated by the same reference numbers and description thereof is omitted.

The equalizer 306 in FIG. 7 includes channel estimation units 361 and 362, division units 363 and 364, a quality determining unit 365, and a selection unit 366. The channel estimation unit 361 and the channel estimation unit 362 respectively calculate channel responses CR31 and CR32 corresponding to data carriers from the received signal (OFDM signal FS in the frequency domain) using predetermined different estimation schemes.

The division unit 363 carries out equalization by dividing the OFDM signal FS in the frequency domain output from the FFT unit 5 by the channel response CR31, i.e., reduces or eliminates a waveform distortion introduced by the transmission channel. The division unit 363 outputs the result of the equalization to the selection unit 366 as an equalized signal ES31. The division unit 364 carries out equalization by dividing the OFDM signal FS in the frequency domain by the channel response CR32, and outputs the result of the equalization to the selection unit 366 as an equalized signal ES32.

The quality determining unit 365 calculates a quality value in the same manner as the quality determining unit 265 in FIG. 5 using the channel responses CR31 and CR32 instead of the channel responses CR21 and CR22, and outputs, to the selection unit 366, a selection signal indicative of one of the channel responses CR31 and CR32 corresponding to a better quality value. The selection unit 366 selects one of the equalized signals ES31 and ES32 obtained using a channel response indicated by the selection signal output from the quality determining unit 365, and outputs the result of the selection to the error corrector 7 as an equalized signal.

Estimation schemes of channel response used in the channel estimation units 361 and 362 are selected in the same manner as that of the channel estimation units 261 and 262 in FIG. 5.

The quality calculator 312 calculates a quality value QA of the received signal in the same manner as the quality calculator 12 in FIG. 1 from the channel response CR31 estimated by the channel estimation unit 361 and the OFDM signal FS in the frequency domain, and outputs the result of the calculation to the operation controller 314. The quality calculator 313 calculates a quality value QB of the received signal in the same manner as the quality calculator 12 in FIG. 1 from the channel response CR32 estimated by the channel estimation unit 362 and the OFDM signal FS in the frequency domain, and outputs the result of the calculation to the operation controller 314.

When any of the quality values QA and QB output from the quality calculators 312 and 313 is equal to or higher than a predetermined value, the operation controller 314 determines that a quality of the received signal is sufficiently good, and generates an operation control signal to stop at least a portion of the channel estimation units 361 and 362 and the division units 363 and 364 that correspond to a lower quality value, and of the quality determining unit 365. That is, when the quality value QB is equal to or higher than a predetermined value and the quality value QB is higher than the quality value QA, the operation controller 314 generates the operation control signals CT31 and CT33 indicating a halt of operation, and when the quality value QA is equal to or higher than the predetermined value and the quality value QA is equal to or higher than the quality value QB, the operation controller 314 generates operation control signals CT32 and CT33 indicating a halt of operation.

The channel estimation unit 361 and the division unit 363 include computing elements. When the operation control signal CT31 indicates a halt of operation, at least a portion of the channel estimation unit 361 and the division unit 363 halts in the same manner as the channel estimation unit 262 and the division unit 264 in FIG. 5. The channel estimation unit 362 and the division unit 364 include computing elements. When the operation control signal CT32 indicates a halt of operation, at least a portion of the channel estimation unit 362 and the division unit 364 halts in the same manner as the channel estimation unit 262 and the division unit 264 in FIG. 5.

The quality determining unit 365 includes a computing element. When the operation control signal CT33 indicates a halt of operation, at least a portion of the quality determining unit 365 halts in the same manner as the quality determining unit 265 in FIG. 5. Especially when the quality value QB is equal to or higher than the predetermined value and the quality value QB is higher than the quality value QA, the operation control signal CT33 indicating a halt of operation corresponding to the channel estimation unit 361 is output. Therefore, the quality determining unit 365 halts the calculating operation of a quality value corresponding to the channel estimation unit 361. When the quality value QA is equal to or higher than the predetermined value and the quality value QA is higher than the quality value QB, the operation control signal CT33 indicating a halt of operation corresponding to the channel estimation unit 363 is output. Therefore, the quality determining unit 365 halts the calculating operation of a quality value corresponding to the channel estimation unit 363.

When a quality value of one of the quality values QA and QB corresponding to the channel estimation unit that keeps operating is less than the predetermined value, the operation controller 314 determines that it is not appropriate to use the channel response obtained by the channel estimation unit, and generates operation control signals CT31, CT32, and CT33 indicating operation. At that time, the channel estimation units 361 and 362, the division units 363 and 364, and the quality determining unit 365 carry out the operation such as calculation as usual. The quality determining unit 365 determines a suitable channel estimation scheme in accordance with a channel condition, and a signal that is equalized using a channel response obtained by the estimation scheme is selected. Therefore, it is possible to keep a quality of the equalized signal, and to reduce errors.

According to the embodiment, as described above, when a channel condition is relatively good, power consumed by operation such as calculation can be reduced. Since any of the channel estimation units 361 and 362 can be selected as the channel estimation unit that keeps operating, it is possible to always use an appropriate channel response for equalization.

Although the receiver includes two channel estimation units 361 and 362 in this embodiment, the receiver may include three or more channel estimation units. In this case, it is preferable that the receiver includes an equal number of division units and quality calculators as the channel estimation units, and includes a quality determining unit that makes a selection from a plurality of channel estimation units in the same manner as the quality determining unit 365.

Although the selection unit 366 selects one of the outputs of the division units 363 and 364 in this embodiment, the equalizer 306 may select one of the channel responses CR31 and CR32 in accordance with a selection signal that is output from the quality determining unit 365, and may divide the OFDM signal FS in the frequency domain by the selected channel response.

The receiver receives the OFDM signal as one example in each of the above embodiments, but the receiver may receive a signal of other format only if the receiver includes a plurality of channel estimation units. A channel response may be obtained without using a pilot signal.

Conditions, under which the receiver of the first to third embodiments makes the determination on a quality value when an operation control signal is generated, may appropriately be changed in accordance with a transmission scheme of a signal to be received (i.e., a modulation scheme or an error correcting code rate).

A case where the receiver receives one of a QPSK modulated signal and 16QAM (Quadrature Amplitude Modulation) modulated signal will be described as an example. Generally, the QPSK modulated signal has higher tolerance to disturbance as compared with the 16QAM modulated signal. Therefore, even if the obtained quality values are the same, if the received signal is the QPSK modulated signal, the operation of the channel estimation units can be halted, but if the received signal is the 16QAM modulated signal, the operation cannot be halted in some cases. Hence, when the received signal is the QPSK modulated signal, the determining condition is changed so that an operation control signal indicating a halt of operation is generated even when a lower quality value is obtained. With this, it is possible to increase chances in which power consumption of the receiver is reduced by adding a slight device cost.

As described above, according to the present invention, it is possible to reduce the power consumption while keeping the receiver performance and therefore, the invention is useful for the receiver.

What is claimed is:

1. A receiver for receiving a signal transmitted through a transmission channel, comprising:
an equalizer; and
a first quality calculator that obtains a first quality value of the received signal, wherein
the equalizer includes
a first channel estimation unit that estimates a first channel response of the transmission channel from the received signal using a first estimation scheme; and
a second channel estimation unit that estimates a second channel response of the transmission channel from the received signal using a second estimation scheme,
the equalizer equalizes the received signal using the first or second channel response and outputs the equalized signal, and
a portion of the second channel estimation unit halts depending on the first quality value.

2. The receiver of claim 1, wherein
the equalizer further includes a scheme control unit,
the second channel estimation unit obtains, as the second channel response, a channel response corresponding to the second estimation scheme that is successively selected from a plurality of predetermined estimation schemes,
the scheme control unit selects optimal one of the plurality of predetermined estimation schemes based on the second channel response, and informs the first channel estimation unit of the selected estimation scheme,
the first channel estimation unit estimates the first channel response using the estimation scheme informed from the scheme control unit as the first estimation scheme, and
the equalizer equalizes the received signal using the first channel response.

3. The receiver of claim 2, wherein
a portion of the scheme control unit halts depending on the first quality value.

4. The receiver of claim 1, wherein the equalizer
includes a quality determining unit that determines which one of parameters, representing a quality of the received signal, respectively corresponding to the first and second channel responses indicates better quality, and
equalizes the received signal using either one of first and second channel responses that is indicated by the result of determination of the quality determining unit.

5. The receiver of claim 4, wherein
a portion of the quality determining unit halts depending on the first quality value.

6. The receiver of claim 4, further comprising:
a second quality calculator that calculates a second quality value using the received signal and the second channel response, wherein
a portion of the first channel estimation unit halts depending on the second quality value.

7. The receiver of claim 6, wherein
a portion of the second channel estimation unit halts when the first quality value is equal to or higher than a predetermined value and the first quality value is equal to or higher than the second quality value, and
a portion of the first channel estimation unit halts when the second quality value is equal to or higher than the predetermined value and the second quality value is higher than the first quality value.

8. The receiver of claim 6, wherein
a portion of the quality determining unit halts depending on the first and second quality values.

9. The receiver of claim 1, wherein
the first quality calculator obtains the first quality value using the first channel response.

10. The receiver of claim 1, further comprising:
an error corrector that carries out error correction operation about a signal equalized by the equalizer, and that outputs a number of bits whose errors are corrected, wherein
the first quality calculator obtains the first quality value based on the number of bits whose errors are corrected.

11. The receiver of claim 1, wherein
a portion of the second channel estimation unit halts when the first quality value is equal to or higher than a predetermined value.

12. The receiver of claim 1,
the second channel estimation unit includes a computing element used for estimating the second channel response, and
a portion of the second channel estimation unit is halted by stopping supply of a clock to the computing element.

13. The receiver of claim 1, wherein
the second channel estimation unit includes a computing element used for estimating the second channel response, and
a portion of the second channel estimation unit is halted by maintaining a constant level of an input signal to the computing element.

14. The receiver of claim 1, wherein
the second channel estimation unit includes a computing element used for estimating the second channel response, and
a portion of the second channel estimation unit is halted by changing a level of an enable signal that controls operation of the computing element to a level indicating that the operation should be halted.

15. A receiving method for receiving a signal transmitted through a transmission channel, comprising the steps of:
estimating a first channel response of the transmission channel from the received signal using a first estimation scheme,
estimating a second channel response of the transmission channel from the received signal using a second estimation scheme,
equalizing the received signal using the first or second channel response,
obtaining a quality value of the received signal, and
halting a portion of operation for estimating the second channel response depending on the quality value.
